(19) United States
(12) Patent Application Publication
(10) Pub. No.: US 2025/0359055 A1
(43) Pub. Date: Nov. 20, 2025

(54) INTEGRATED CIRCUIT MEMORY DEVICES WITH VERTICAL INTEGRATION AND COMMON SOURCE PLATES

(71) Applicant: Samsung Electronics Co., Ltd., Suwon-si (KR)

(72) Inventors: Jeongyoon Yeo, Suwon-si (KR); Myung Uk Park, Suwon-si (KR); Shinhwan Kang, Suwon-si (KR); Cheon An Lee, Suwon-si (KR); Ik-Hyung Joo, Suwon-si (KR)

(21) Appl. No.: 18/966,535

(22) Filed: Dec. 3, 2024

(30) Foreign Application Priority Data
May 14, 2024 (KR) 10-2024-0063173

(51) Int. Cl. H10B 43/27; H10B 43/10; H10B 43/35; H10B 43/40

(52) U.S. Cl. CPC H10B 43/27; H10B 43/10; H10B 43/35; H10B 43/40

(57) ABSTRACT

An integrated circuit memory device includes a common source plate having a semiconductor material of a first conductivity type therein, and a plurality of word lines (including a dummy word line) extending on a bottom surface of the common source plate and spaced apart from each other in a first direction, which is perpendicular to the bottom surface of the common source plate. A mold insulating layer is provided, which at least partially surrounds the plurality of word lines, along with a plurality of channel structures that extend through the plurality of word lines and the mold insulating layer in the first direction. A metal layer is also provided, which extends in an upper region inside each of the plurality of channel structures, and is overlapped by the dummy word line in a direction orthogonal to the first direction.

### REFERENCE TO RELATED APPLICATION

This application claims priority to Korean Patent Application No. 10-2024-0063173, filed May 14, 2024, the disclosure of which is hereby incorporated herein by reference.

### BACKGROUND

There is an ongoing need for integrated circuit memory devices that are capable of storing high-capacity data in an electronic system that requires data storage; and, ways to increase the data storage capacity of integrated circuit memory devices are being studied. For example, one of the methods for increasing the data storage capacity of an integrated circuit memory device includes the use of a three-dimensional arrangement of memory cells instead of two-dimensional arrangement of memory cells.

### SUMMARY

The present disclosure describes integrated circuit memory devices with improved electrical characteristics and reliability, according to embodiments of the invention.

According to some aspects of the present disclosure, an integrated circuit memory device may include a common source plate including a semiconductor material of a first conductivity type (e.g., N-type), and a plurality of word lines disposed on a bottom surface of the common source plate and spaced apart from each other in a first direction, which may be perpendicular to the bottom surface of the common source plate. A mold insulating layer is provided, which at least partially surrounds the plurality of word lines. In addition, a plurality of channel structures are provided that extend through the plurality of word lines and the mold insulating layer in the first direction. A metal layer is provided, which extends on an upper region inside each of the plurality of channel structures. Furthermore, the plurality of word lines may include a dummy word line, and at least a portion of the dummy word line may overlap the metal layer in a horizontal direction, which is orthogonal to the first direction.

According to some aspects of the present disclosure, an integrated circuit memory device may include a peripheral circuit region, and a memory cell region on the peripheral circuit region. The peripheral circuit region includes: a peripheral circuit substrate, a plurality of circuit elements formed on the peripheral circuit substrate, a peripheral circuit wiring layer electrically connected to each of the plurality of circuit elements, and an interlayer insulating layer that extends on the peripheral circuit substrate and surrounds the plurality of circuit elements and the peripheral circuit wiring layer. In addition, the memory cell region includes: a common source plate including a semiconductor material of a first conductivity type, a plurality of word lines (including dummy word line) that extend on a bottom surface of the common source plate and are spaced apart from each other in a first direction perpendicular to the bottom surface of the common source plate, a mold insulating layer surrounding the plurality of word lines, a plurality of channel structures extending through the plurality of word lines and the mold insulating layer in the first direction, a metal layer extending within an upper region inside each of the plurality of channel structures, and a bit line extending under the plurality of channel structures. Further, according to some embodiments, at least a portion of the dummy word line overlaps the metal layer in a horizontal direction, which is orthogonal to the first direction.

According to further aspects of the present disclosure, an integrated circuit memory device may include a common source plate including a semiconductor material (e.g., N-type polysilicon), a plurality of word lines (including dummy word line) extending on a bottom surface of the common source plate and spaced apart from each other in a first direction that is perpendicular to the bottom surface of the common source plate, a mold insulating layer at least partially surrounding the plurality of word lines, a plurality of channel structures extending through the plurality of word lines and the mold insulating layer in the first direction, a metal layer extending in an upper region inside each of the plurality of channel structures, in which the metal layer may be in contact with inside of a channel layer of the plurality of channel structures and the bottom surface of the common source plate, and a bit line extending under the plurality of channel structures. Advantageously, the memory device is configured such that an application of a predetermined bias voltage to the dummy word line operates to lower a Schottky barrier between the metal layer and the channel layer. In addition, according to some embodiments, at least a portion of the dummy word line may overlap the metal layer in a horizontal direction that is orthogonal to the first direction.

According to some aspects of the present disclosure, by placing the common source plate including the n-type semiconductor material and the channel structure in contact with the common source plate, and placing the metal layer having a low relative work function in contact with the channel layer of the common source plate and the channel structure, the leakage current of the integrated circuit memory device can be reduced and the erase operation can be facilitated, thereby improving the performance of the integrated circuit memory device.

### BRIEF DESCRIPTION OF THE DRAWINGS

The above and other objects, features and advantages of the present disclosure will become more apparent to those of ordinary skill in the art by describing in detail exemplary embodiments thereof with reference to the accompanying drawings, in which:

FIG. 1 is a circuit diagram conceptually illustrating a memory array region of a semiconductor device;

FIG. 2 is an example layout diagram provided to explain an integrated circuit memory device;

FIG. 3 is a cross-sectional view taken along the cross section A-A′ of FIG. 2;

FIG. 4A is an enlarged view of the region EX 1 of FIG. 3;

FIG. 4B is an enlarged view of the region EX 1 of FIG. 3, provided to explain an integrated circuit memory device according to another aspect of the present disclosure;

FIG. 4C is an enlarged view of the region EX 1 of FIG. 3, provided to explain an integrated circuit memory device according to another aspect of the present disclosure;

FIG. 4D is an enlarged view of the region EX 1 of FIG. 3, provided to explain an integrated circuit memory device according to another aspect of the present disclosure;

FIG. 4D is an enlarged view of the region EX 1 of FIG. 3, provided to explain an integrated circuit memory device according to another aspect of the present disclosure;

FIG. 4F is an enlarged view of the region EX 1 of FIG. 3, provided to explain an integrated circuit memory device according to another aspect of the present disclosure;

FIGS. 5 to 12 are diagrams showing intermediate stages, provided to explain a method for manufacturing an integrated circuit memory device according to some aspects of the present disclosure;

FIG. 13 is a conceptual diagram schematically illustrating an electronic system including an integrated circuit memory device;

FIG. 14 is a perspective view schematically illustrating an electronic system including a 3D integrated circuit memory device according to aspects of the present disclosure; and

FIG. 15 is a cross-sectional view taken along the cross section B-B of FIG. 14.

### DETAILED DESCRIPTION

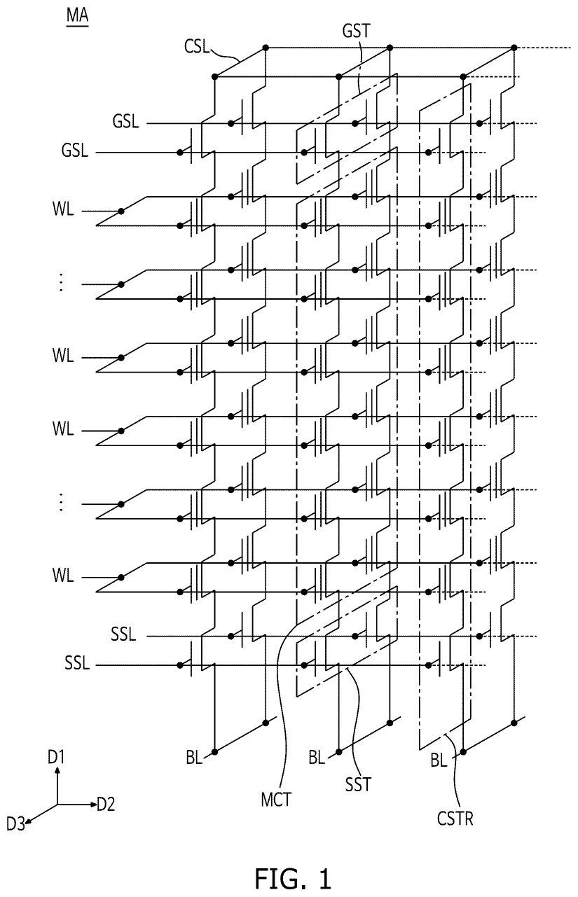

FIG. 1 is a circuit diagram conceptually illustrating a memory array region MA of a semiconductor device. Referring to FIG. 1, the memory array region MA of the semiconductor device may include a common source line CSL, a plurality of bit lines BL, and a plurality of cell strings CSTR disposed between the common source line CSL and the plurality of bit lines BL. The common source line CSL, the plurality of cell strings CSTR, and the plurality of bit lines BL may be disposed along a first direction D1.

The common source line CSL may extend in a second direction D2 that is perpendicular to the first direction. In some embodiments, the plurality of common source lines CSL may be arranged two-dimensionally. For example, the plurality of common source lines CSL may be spaced apart from each other and may extend in the second direction D2, respectively. The same voltage may be applied to the common source line CSL, or different voltages may be applied to be separately controlled.

The plurality of bit lines BL may be arranged two-dimensionally. For example, the plurality of bit lines BL may be spaced apart from each other and may extend in a third direction D3 intersecting the second direction D2. Each of the bit lines BL may be connected in parallel with the plurality of cell strings CSTR.

The plurality of cell strings CSTR may be coupled in common to the common source line CSL. The plurality of cell strings CSTR may be disposed between the common source line CSL and the plurality of bit lines BL. Each of the plurality of cell strings CSTR may include memory cell transistors MCT, a ground select transistor GST, and a string select transistor SST. The memory cell transistors MCT, the ground select transistor GST, and the string select transistor SST may be connected to each other in series. For example, the memory cell transistors MCT may be connected in series between the ground select transistor GST and the string select transistor SST. Each of the memory cell transistors MCT may include information storage regions capable of storing information. For example, each of the memory cell transistors MCT may include a data storage element.

There may be a plurality of ground select transistors GST and the ground select transistors GST may be electrically connected to the common source line CSL. There may be a plurality of string select transistors SST and the string select transistors SST may be electrically connected to the bit line BL. In addition, a ground select line GSL, a plurality of word lines WL, and a string select line SSL may be disposed between the common source line CSL and the bit line BL. The ground select transistors GST may be controlled by the ground select line GSL. For example, the ground select line GSL may be used as a gate electrode of the ground select transistors GST. The common source line CSL may be connected in common to a source of the ground select transistors GST. The string select transistor SST may be controlled by the string select line SSL. The memory cell transistors MCT may be controlled by the plurality of word lines WL. For example, the string select line SSL may be used as a gate electrode of the string select transistors SST, and the plurality of word lines WL may be used as gate electrodes of the memory cell transistors MCT.

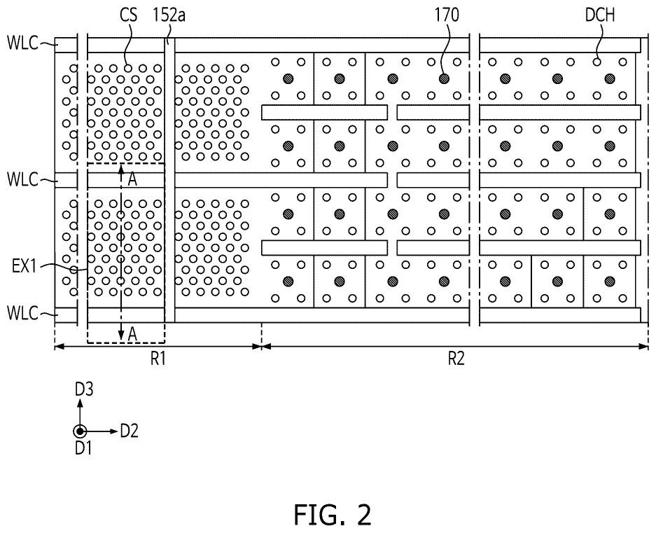

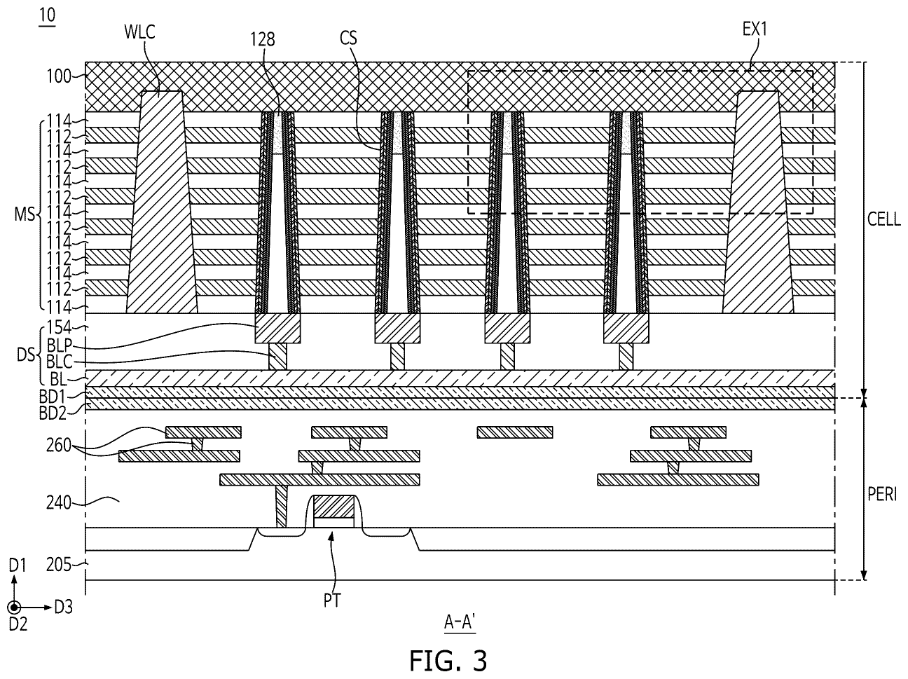

FIG. 2 is an example layout diagram provided to explain an integrated circuit memory device. FIG. 3 is a cross-sectional view taken along the cross section A-A′ of FIG. 2. Referring to FIGS. 2 and 3, an integrated circuit memory device 10 according to some aspects may include a memory cell region CELL and a peripheral circuit region PERI.

The memory cell region CELL may include a cell array region R1 and an extension region R2. A memory cell array region (e.g., the MA of FIG. 1) including a plurality of memory cells may be formed in the cell array region R1. For example, a channel structure CS, a bit line BL, a word line 112, etc. to be described below may be disposed in the cell array region R1. The extension region R2 may be disposed around the cell array region R1. The word lines 112 to be described below may be stacked in the extension region R2 in a stepwise manner.

The memory cell region CELL may include a common source plate 100 including a semiconductor material, a mold structure MS disposed on a bottom surface of the common source plate 100 and including a plurality of word lines 112 spaced apart from each other in the first direction D1 that is perpendicular to the bottom surface of the common source plate 100 and mold insulating layers 114 surrounding the plurality of word lines 112, and a plurality of channel structures CS extending through the plurality of word lines 112 and the mold insulating layer 114 in the first direction D1.

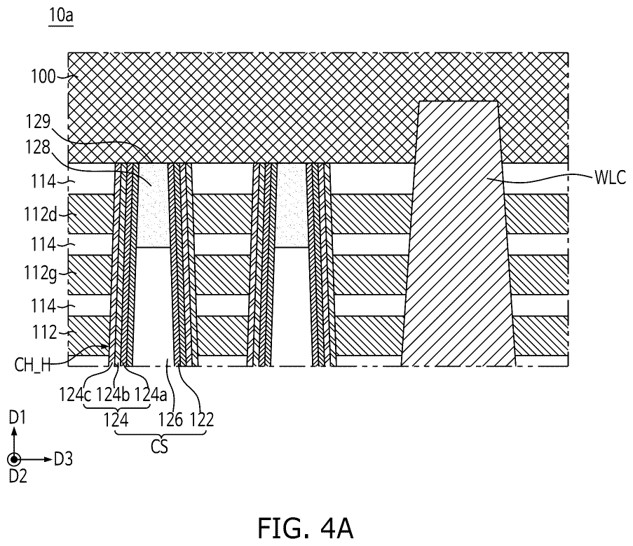

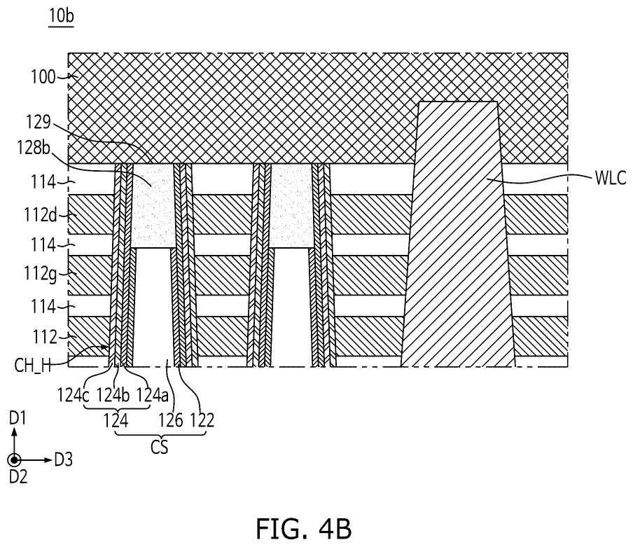

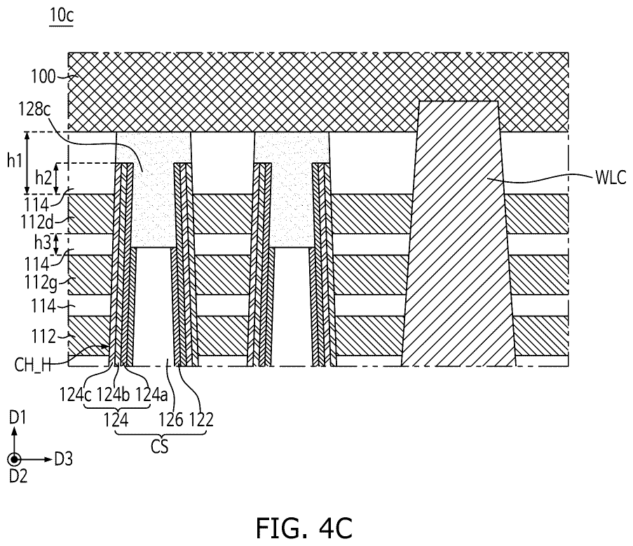

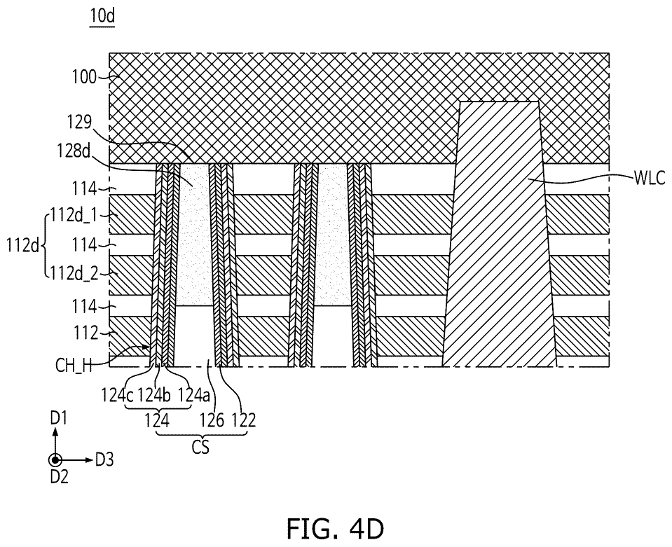

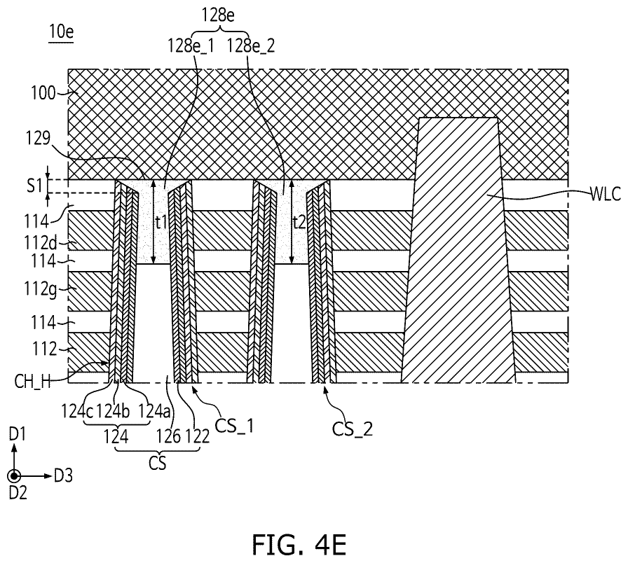

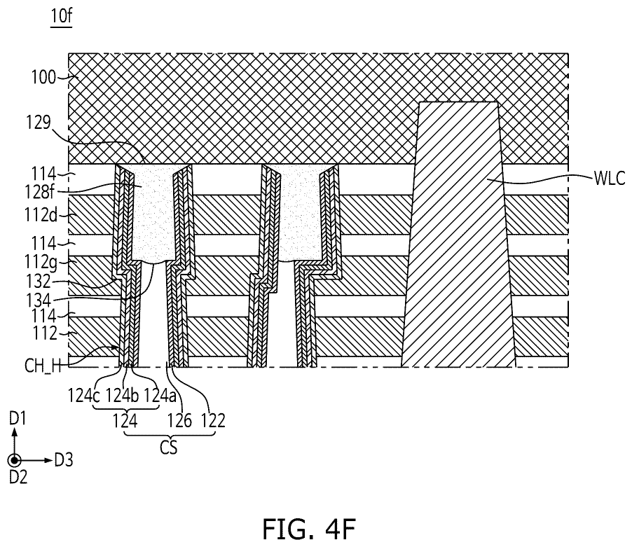

The common source plate 100 may be entirely disposed on an upper surface of the mold structure MS. The common source plate 100 may be in contact with, or at least electrically connected to, the channel layer (e.g., a channel layer 122 of FIG. 4A) of the channel structure CS. The common source plate 100 may be connected to a channel layer to function as a common source line (e.g., CSL in FIG. 2) of the integrated circuit memory device 10. Although not illustrated, a first interlayer insulating film may be disposed on the common source plate 100, and contact pads for connecting to upper portions of the plurality of channel structures CS may be formed in the first interlayer insulating film. Accordingly, the channel structure CS may be electrically connected to the contact pad through the common source plate 100. The common source plate 100 may include a semiconductor material. For example, the semiconductor material of the common source plate 100 may include N-type polysilicon.

The mold structure MS may include a plurality of word lines 112 spaced apart from each other in the first direction D1 which is a vertical direction, and the mold insulating layers 114 surrounding the plurality of word lines 112. The word lines 112 may correspond to gate electrodes. The mold structure MS may be disposed on the bottom surface of the common source plate 100. The plurality of word lines 112 may be spaced apart from each other in the first direction, which is perpendicular to the bottom surface of the common source plate 100. The mold insulating layer 114 may not only surround the word line 112 but also surround other components in the memory cell region CELL, such as contact plugs. In the cell array region R1, the mold structure MS may include a structure in which the plurality of word lines 112 and the mold insulating layers 114 are alternately stacked. As will be understood by those skilled in the art, to support efficient electrical contact thereto, the plurality of word lines 112 may be stacked in a stepwise manner in the extension region R2. For example, the plurality of word lines 112 may extend to different lengths along the second direction D2. Accordingly, a step may be formed between the plurality of word lines 112. In some embodiments, a dummy channel structure DCH may be formed in the mold structure MS of the extended region R2. The dummy channel structure DCH may be formed in a shape similar to that of the channel structure CS to reduce the stress applied to the mold structure MS in the extended region R2.

A block separation structure WLC may extend in the second direction D2 to separate or partition the mold structure MS. The mold structure MS may be separated by a plurality of block separation structures WLC to form a plurality of memory cell blocks. For example, two adjacent block separation structures WLC may define one memory cell block therebetween. A plurality of channel structures CS may be disposed in each of the memory cell blocks defined by the block separation structures WLC. Although not wishing to be bound by any particular configuration, the number of channel structures CS arranged in the zigzag form along the third direction D3 in one memory cell block may vary, without being limited to that illustrated in FIG. 2.

In some embodiments, the block separation structures WLC may include an insulating material, and the insulating material may fill the block separation structures WLC. For example, the insulating material may include at least one of silicon oxide, silicon nitride, and silicon oxynitride, but is not limited thereto. Although not illustrated, a string separation structure may be formed in the mold structure MS. The string separation structure may extend in the second direction D2 to cut the word line 112. The string separation structure may cut a portion of the word line 112 disposed on the uppermost portion. Each of the memory cell blocks defined by the block separation structure WLC may be divided by the string separation structure to form a plurality of string regions. For example, the string separation structure may define two string regions in one memory cell block.

A cell contact structure 170 may be connected to the word line 112 in the extension region R2. The cell contact structure 170 may extend through the mold structure MS in the first direction D1. The cell contact structure 170 may be connected to the pad region of each word line 112. Each of the word lines 112 may correspond to any one of the ground select line GSL, the plurality of word lines WL, and the string select line SSL of FIG. 2. In addition, as will be described below, in some aspects, a word line adjacent to the ground select line GSL may correspond to a dummy word line.

Moreover, the mold insulating layer 114 may include an insulating material, for example, at least one of silicon oxide, silicon nitride, and silicon oxynitride, but is not limited thereto. For example, the mold insulating layer 114 may include the silicon oxide.

A plurality of channel structures CS may be formed on the mold structure MS of the cell array region R1. The plurality of channel structures CS may extend through the mold structure MS in a vertical direction (hereinafter, referred to as the first direction D1) that intersects the upper surface of the mold structure MS. For example, the plurality of channel structures CS may have a pillar shape (e.g., cylindrical shape) extending in the first direction D1. In some embodiments, the width of the channel structure CS may become wider as the distance from the upper surface of the mold structure MS increases. However, depending on designs, the width of the channel structure CS may become narrower as the distance from the upper surface of the mold structure MS increases or may be substantially the same at all vertical levels.

In some embodiments, the plurality of channel structures CS may be arranged in a zigzag form. For example, as illustrated in FIG. 2, the plurality of channel structures CS may be arranged to cross each other in the second direction D2 and the third direction D3. The plurality of channel structures CS arranged in the zigzag form may further improve the degree of integration of the integrated circuit memory device 10. In some embodiments, the plurality of channel structures CS may be arranged in a honeycomb form.

The memory cell region CELL may further include a metal layer 128 disposed in an upper region inside each of a plurality of channel structures. A partial region of the metal layer 128 (e.g., an upper surface of the metal layer 128) may be in contact with the bottom surface of the common source plate 100.

Details of the components of the channel structure CS and various aspects regarding the positions and shapes of the metal layer 128 will be described in detail with reference to FIGS. 4A to 4F. The memory cell region CELL may further include a drain structure DS disposed under the mold structure MS. The drain structure DS may include the bit line BL, a bit line contact BLC, a bit line contact pad BLP, and a second interlayer insulating film 154. The bit line BL may be formed under the mold structure MS and the second interlayer insulating film 154. The bit line BL may extend in the third direction D3 and intersect the block separation structure WLC. In addition, the bit line BL may extend in the third direction D3 and be connected to the plurality of channel structures CS arranged along the third direction D3. For example, the bit line contact pad BLP and the bit line contact BLC connected to one end of each of the channel structures CS may be formed in the second interlayer insulating film 154. The bit line BL may be electrically connected to the channel structures CS via the bit line contact pad BLP and the bit line contact BLC.

The peripheral circuit region PERI may include a peripheral circuit substrate 205, a plurality of circuit elements PT formed on the peripheral circuit substrate 205, a peripheral circuit wiring layer 260 connected to each of the plurality of circuit elements PT, and an interlayer insulating layer 240 formed on the peripheral circuit substrate 205 to surround the plurality of circuit elements PT and the peripheral circuit wiring layer 260.

The peripheral circuit substrate 205 may be disposed under the drain structure DS. For example, an upper surface of the peripheral circuit substrate 205 may face a lower surface of the drain structure DS. For example, the peripheral circuit substrate 205 may include a semiconductor substrate such as a silicon substrate, a germanium substrate, or a silicon-germanium substrate. Alternatively, the peripheral circuit substrate 205 may also include a silicon-on-insulator (SOI) substrate or a germanium-on-insulator (GOI) substrate, etc.

The circuit elements PT may be formed on the peripheral circuit substrate 205. The circuit elements PT may form a peripheral circuit that controls an operation of the integrated circuit memory device 10. For example, the circuit elements PT may include a control logic, a row decoder, a page buffer, etc. And, in some embodiments, the circuit elements PT may include a transistor, but are not limited thereto. For example, the circuit elements PT may include not only various active elements such as transistors, but also various passive elements such as capacitors, registers, and inductors.

The integrated circuit memory device 10 may further include bonding structures BD1 and BD2 for bonding between the memory cell region CELL and the peripheral circuit region PERI. A first bonding structure BD1 of the memory cell region CELL and a second bonding structure BD2 of the peripheral circuit region PERI may be bonded to each other. The portions for bonding of the first bonding structure BD1 and the second bonding structure BD2 may be formed of copper (Cu).

FIG. 4A is an enlarged view of the region EX 1 of FIG. 3. As illustrated in FIG. 4, the channel structure CS of the integrated circuit memory device 10a may include a channel hole CH_H extending in the first direction D1, and a charge storage structure 124 and the channel layer 122 stacked in order on an inner sidewall of the channel hole CH_H. The channel layer 122 may extend through the plurality of word lines 112 and a plurality of mold insulating layers 114 in the first direction D1. Although it is illustrated that the channel layer 122 has a cup shape, this is merely example. For example, the channel layer 122 may have various shapes such as a cylindrical shape, a square cylindrical shape, a filled pillar shape, etc. For example, the channel layer 122 may include a semiconductor material such as single crystal silicon, polycrystalline silicon, an organic semiconductor material, and a carbon nanostructure, but is not limited thereto.

The charge storage structure 124 may be disposed outside the channel layer 122. The charge storage structure 124 may be disposed between the channel layer 122 and a stack structure (i.e., the mold structure) of the word line 112 and the mold insulating layer 114. For example, the charge storage structure 124 may extend along an outer surface of the channel layer 122. In some embodiments, the charge storage structure 124 may include at least one of silicon oxide, silicon nitride, silicon oxynitride, and a high-k material having a higher dielectric constant than the silicon oxide. The high-k material may include at least one of aluminum oxide, hafnium oxide, lanthanum oxide, tantalum oxide, titanium oxide, lanthanum hafnium oxide, lanthanum aluminum oxide, dysprosium scandium oxide, and a combination thereof.

The charge storage structure 124 may be formed of multiple layers. For example, the charge storage structure 124 may include a tunnel insulating film 124a, a charge storage film 124b, and a blocking insulating film 124c, which may be stacked in order on the outer surface of the channel layer 122. In some embodiments, the tunnel insulating film 124a may include the silicon oxide or a high-k material (e.g., aluminum oxide (Al₂O₃), hafnium oxide (HfO₂)) having a higher dielectric constant than the silicon oxide. For example, the charge storage film 124b may include the silicon nitride. For example, the blocking insulating film 124c may include the silicon oxide or a high-k material (e.g., aluminum oxide (Al₂O₃) or hafnium oxide (HfO₂)) having a higher dielectric constant than the silicon oxide.

The channel structure CS may further include a filling pattern 126. The filling pattern 126 may be formed to fill the inside of the channel layer 122. For example, the filling pattern 126 may include an insulating material, for example, silicon oxide, but is not limited thereto. The metal layer 128 may be disposed in an upper region inside the channel structure CS. In some embodiments, the metal layer 128 may be in contact with inside of the channel layer 122 of the channel structure CS and the bottom surface of the common source plate 100. For example, a side surface of the metal layer 128 may be surrounded by the channel layer 122. Furthermore, an upper surface 129 of the metal layer 128 may be in contact with the bottom surface of the common source plate 100. The metal layer 128 may include a metal having a low work function (e.g., a metal having a work function lower than 4.5 eV). For example, the metal layer 128 may include at least one of aluminum (Al), titanium (Ti), and chromium (Cr).

The plurality of word lines 112 may include a dummy word line 112d. The dummy word line 112d may be positioned at an uppermost end of the plurality of word lines 112. For example, the dummy word line 112d may be disposed adjacent to a lower portion of the common source plate 100. In addition, the dummy word line 112d may be disposed adjacent to a ground select line 112g of the plurality of word lines 112. For example, the ground select line 112g may be disposed adjacent to a lower portion of the dummy word line 112d. In some embodiments, at least a portion of the dummy word line 112d may overlap the metal layer 128 in horizontal directions (second and third directions D2 and D3) orthogonal to the first direction D1. For example, as illustrated in FIG. 4A, the uppermost end of the dummy word line 112d may have a lower vertical level than the upper surface 129 of the metal layer 128. In addition, a lowermost end of the dummy word line 112d may have a higher vertical level than a lower surface of the metal layer 128. Alternatively, the lowermost end of the dummy word line 112d may have a lower vertical level than the lower surface of the metal layer 128, and aspects are not limited thereto.

In some embodiments, a predetermined bias voltage may be applied to the dummy word line 112d to lower the Schottky barrier between the metal layer 128 and the channel layer 122 of the plurality of channel structures CS. In this case, the predetermined bias voltage may have a negative voltage value. Advantageously, a metal layer 128 having a low work function may form an ohmic contact with the common source plate 100 doped with n-type impurities. In addition, the metal layer 128 may form a Schottky contact with the channel layer 122. In this case, the Schottky barrier may be lowered by the bias voltage applied through the dummy word line 112d. Through this, erase operation may be easily performed, thereby improving the electrical characteristics of the integrated circuit memory device. In addition, the common source plate 100 of an n-type semiconductor material that does not include a p-type semiconductor material does not form a P-N contact, thereby preventing leakage current problems caused by integration of the integrated circuit memory devices.

FIG. 4B is an enlarged view of the region EX 1 of FIG. 3, provided to explain an integrated circuit memory device according to another aspect of the present disclosure. The integrated circuit memory device 10b of FIG. 4B may be substantially the same as the integrated circuit memory device 10a described with reference to FIGS. 1 to 4A, except for certain differences in the arrangement of the metal layer 128b and the channel structure CS with respect to each other. In describing certain aspects with reference to FIG. 4B, details overlapping with FIGS. 1 to 4A will be briefly described or omitted.

In some embodiments, the metal layer 128b may be in contact with the inner side of the charge storage structure 124 of the plurality of channel structures CS and the bottom surface of the common source plate 100. For example, the metal layer 128b may be disposed above the channel layer 122 and the filling pattern 126. That is, the channel layer 122 and the filling pattern 126 may extend up to the lower surface of the metal layer 128b along the first direction D1. In addition, the charge storage structure 124 of the channel structure CS, that is, the tunnel insulating film 124a, the charge storage film 124b, and the blocking insulating film 124c may extend to the side surface of the metal layer 128b. Accordingly, the side surface of the metal layer 128b may be surrounded by the tunnel insulating film 124a (i.e., the charge storage structure 124). In addition, the upper surface of the metal layer 128b may be in contact with the bottom surface of the common source plate 100.

FIG. 4C is an enlarged view of the region EX 1 of FIG. 3, provided to explain an integrated circuit memory device according to another aspect of the present disclosure. The integrated circuit memory device 10c of FIG. 4C may be substantially the same as the integrated circuit memory device 10a described above with reference to FIGS. 1 to 4A, except for certain differences in the shape of the metal layer 128c. In describing certain aspects with reference to FIG. 4C, details overlapping with FIGS. 1 to 4A will be briefly described or omitted.

In some embodiments, the metal layer 128c may be in contact with the bottom surface of the common source plate 100, but at least a partial region of the side surface of the metal layer 128c may not be in contact with the mold insulating layer 114. For example, the metal layer 128c may extend in the channel structure CS along the first direction D1, and further extend from the uppermost end of the charge storage structure 124 to the bottom surface of the common source plate 100 in the first direction D1, with the width of the metal layer 128c extending to an outer surface of the charge storage structure 124 in the horizontal direction. Accordingly, a partial region of the side surface of the metal layer 128c outside of the channel structure CS may be surrounded by the mold insulating layer 114, and in this case, the upper region of the channel structure CS may have a region including only the metal layer 128c. Furthermore, an uppermost end of the metal layer 128c may have a higher vertical level than the uppermost end of the charge storage structure 124.

In some embodiments, the mold insulating layer 114 may have a predetermined thickness (or height) or more. For example, a thickness (or height) h1 of an uppermost mold insulator of the plurality of mold insulating layers 114, which is in contact with the metal layer 128c, may be greater than a thickness (or height) h3 of the other mold insulators. In addition, a thickness (or height) h2 by which the charge storage structure 124 is extended into the uppermost mold insulator may be less than the thickness (or height) h1 of the uppermost mold insulator.

FIG. 4C illustrates that the channel layer 122 extends up to the lower surface of the metal layer 128b along the first direction D1 and that the side surface of the metal layer 128b is surrounded by the tunnel insulating film 124a, but aspects are not limited thereto, and as illustrated in FIG. 4A, it is also possible that the side surface of the metal layer 128c is surrounded by the channel layer 122. In addition, FIG. 4C illustrates that the width of the metal layer 128c progressively decreases from the inside of the channel structure CS to the upper portion of the channel structure CS, but aspects are not limited thereto, and the width of the metal layer 128c may be substantially the same at all heights inside the channel structure CS, or the width of the metal layer 128c may increase toward the top.

FIG. 4D is an enlarged view of the region EX 1 of FIG. 3, provided to explain an integrated circuit memory device according to another aspect of the present disclosure. The integrated circuit memory device 10d of FIG. 4D may be substantially the same as the integrated circuit memory device 10a described above with reference to FIGS. 1 to 4A, except for certain differences in the shape of the metal layer 128d. In describing certain aspects with reference to FIG. 4D, details overlapping with FIGS. 1 to 4A will be briefly described or omitted.

In some embodiments, the plurality of word lines 112 may include two or more dummy word lines 112d. The two or more dummy word lines 112d may be two or more word lines at the uppermost end of the plurality of word lines 112. In this case, the two or more dummy word lines 112d may be disposed adjacent to the lower portion of the common source plate 100. For example, a first dummy word line 112d_1 and a second dummy word line 112d_2 may be disposed adjacent to each other. In addition, the first dummy word line 112d_1 may be disposed adjacent to the lower portion of the common source plate 100, and the second dummy word line 112d_2 may be disposed adjacent to the lower portion of the first dummy word line 112d_1.

In this case, the metal layer 128d may be formed to extend in the first direction D1 in the channel structure CS to overlap the two or more dummy word lines 112d in the horizontal directions (second and third directions D2 and D3) orthogonal to the first direction D1. Accordingly, the uppermost end of the metal layer 128d may have a higher vertical level than the uppermost end of the first dummy word line 112d_1, and the lowermost end of the metal layer 128d may have a lower vertical level than the lowermost end of the second dummy word line 112d_2. Alternatively, in some cases, the lowermost end of the metal layer 128d may have a higher vertical level than the lowermost end of the second dummy word line 112d_2.

FIG. 4D is an enlarged view of the region EX 1 of FIG. 3, provided to explain an integrated circuit memory device according to another aspect of the present disclosure. The integrated circuit memory device 10e of FIG. 4E may be substantially the same as the integrated circuit memory device 10a described above with reference to FIGS. 1 to 4A, except for certain differences in the shape of the metal layer 128e. In describing certain aspects with reference to FIG. 4E, details overlapping with FIGS. 1 to 4A will be briefly described or omitted.

In some embodiments, the metal layer 128e may include a region s1 in each of the plurality of channel structures CS, which increases in width toward the upper portion. For example, there may be an inclined upper surface that is inclined inward from an outer upper end of the channel layer 122 of the plurality of channel structures CS and the charge storage structure 124. In this case, the inclined upper surface of the channel layer 122 and the charge storage structure 124 may be in substantially the same plane. Accordingly, the metal layer 128e may extend in the channel structure CS to the inclined upper surface of the channel layer 122 and the charge storage structure 124 along the first direction D1, and extend up to the uppermost end of the channel structure CS (i.e., up to the uppermost end of the blocking insulating film 124c disposed at the outermost side of the charge storage structure 124) while increasing in width along the inclined upper surface. A width of the upper surface of the metal layer 128e in contact with the common source plate 100 may be substantially the same as the width of the channel structure CS.

In some embodiments, the plurality of channel structures CS may include metal layers 128e_1 and 128e_2 having different heights. For example, a height t1 of the first metal layer 128e_1 and a height t2 of the second metal layer 128e_2 may be different from each other.

FIG. 4F is an enlarged view of the region EX 1 of FIG. 3, provided to explain an integrated circuit memory device according to another aspect of the present disclosure. The integrated circuit memory device 10f of FIG. 4F may be substantially the same as the integrated circuit memory device 10a described above with reference to FIGS. 1 to 4A, except for certain differences in the shape of the metal layer 128f. In describing certain aspects with reference to FIG. 4F, details overlapping with FIGS. 1 to 4A will be briefly described or omitted.

In some embodiments, a stepped structure having one or more horizontal surfaces (or approximately horizontal surfaces) may be formed on the inner sidewall of the channel hole CH_H of each of the plurality of channel structures CS. For example, a step (or stepped surface) 132 may be formed on the inner sidewall of the channel hole CH_H. The width of the channel hole CH_H extending in the upper direction (e.g., in the first direction D1) may expand on the step 132 in the horizontal directions (e.g., in the second and third directions D2 and D3). According to the stepped structure of the channel hole CH_H, the charge storage structure 124 and the channel layer 122 may be stacked in order on the inner sidewall of the channel hole CH_H.

In some embodiments, the metal layer 128f may extend in the first direction D1 from an upper level of the channel structure CS to a step level (or to a periphery of the step level) at which the step 132 of the channel structure CS is formed. The metal layer 128f may include a convex portion 134 curved downward from an edge of the step level toward approximately the center of the channel layer 122.

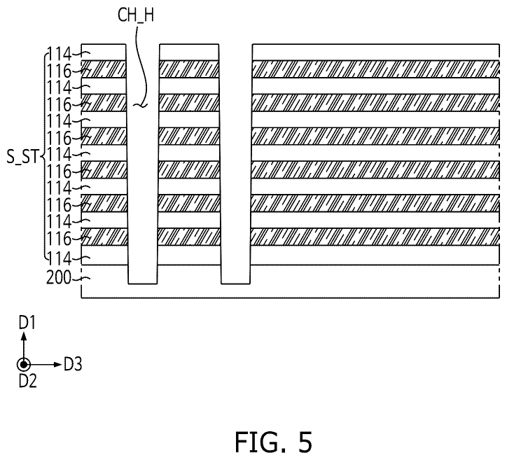

FIGS. 5 to 12 are diagrams showing intermediate stages, provided to explain a method for manufacturing an integrated circuit memory device according to some aspects of the present disclosure. FIGS. 5 through 12 will be described below, mainly focusing on a method for manufacturing the cell array region R1 of the integrated circuit memory device.

Referring to FIG. 5, a method for manufacturing an integrated circuit memory device according to some aspects may include forming a stack structure S_ST on the substrate 200, and forming a channel hole CH_H extending through the stack structure S_ST.

The substrate 200 may be a silicon substrate, or may include other materials, such as silicon germanium (SiGe), silicon germanium on insulator (SGOI), indium antimony, lead tellurium compound, indium arsenic, indium phosphide, gallium arsenic, or gallium antimony, but is not limited thereto. Although not illustrated, an etch stop film may be formed on the substrate 200. The etch stop film may include a material having etch selectivity with respect to the substrate 200. For example, the etch stop film may include a silicon nitride film, but is not limited thereto.

The stack structure S_ST may be formed on the substrate 200. The stack structure S_ST may include the mold insulating layer 114 and a sacrificial layer 116 alternately stacked on each another. The sacrificial layer 116 may include a material having etch selectivity with respect to the mold insulating layer 114. For example, the mold insulating layer 114 may include a silicon oxide film. The sacrificial layer 116 may include a silicon nitride film. However, aspects are not limited thereto. In another aspect, the mold insulating layer 114 may be an insulating film, and the sacrificial layer 116 may be a conductive film.

The channel hole CH_H extending through the stacked structure S_ST, that is, through the stack of alternating mold insulating layers 114 and sacrificial layers 116 may be formed. The channel hole CH_H may be formed such that a portion of the upper portion of the substrate 200 is etched to extend into the substrate 200.

In some embodiments, the channel hole CH_H may be a high aspect ratio contact via. In this case, a stopper region may be formed in advance in a region (e.g., at a lower portion of the substrate 200) that is opposite a start region where the channel hole CH_H starts extending thereinto. In this case, the stopper region may be used as an etch stop film in an etch process. Accordingly, a stepped structure as the one illustrated in FIG. 4F having one or more horizontal surfaces (or approximately horizontal surfaces) may be formed on the inner sidewall of the channel hole CH_H.

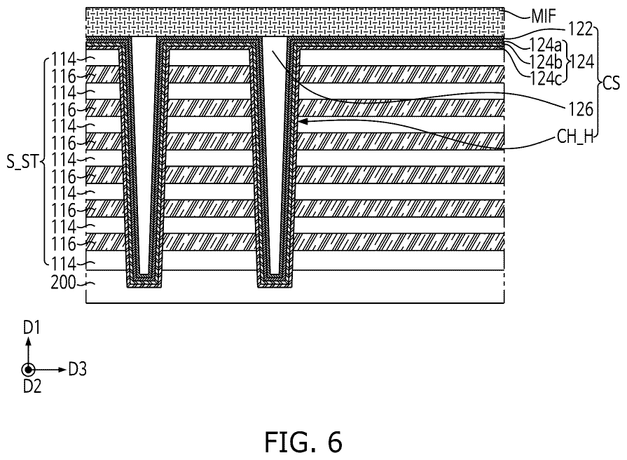

Referring to FIG. 6, the charge storage structure 124, the channel layer 122, and the filling pattern 126 may be formed in order in the channel hole CH_H. In addition, an intermediate insulating film MIF may be formed on the channel layer 122 and the filling pattern 126.

The process of forming the charge storage structure 124 may be performed in the order of forming the blocking insulating film 124c, forming the charge storage film 124b on the blocking insulating film 124c, and forming the tunnel insulating film 124a on the charge storage film 124b. The channel layer 122 may be formed on the charge storage structure 124. The channel layer 122 and the charge storage structure 124 may be formed to extend to a surface, that is, to an upper surface of the stack structure S_ST. The filling pattern 126 may be formed in the channel layer 122, and the intermediate insulating film MIF may be formed on the channel layer 122 and the filling pattern 126.

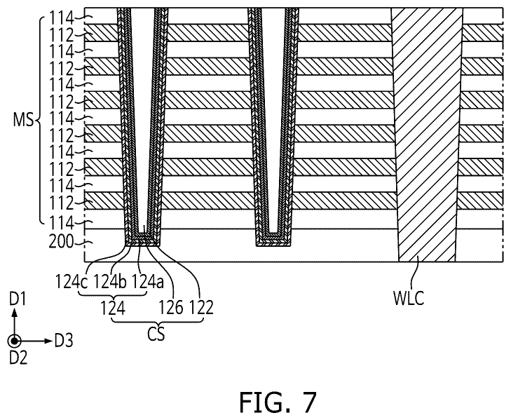

Referring to FIG. 7, the block separation structure WLC extending through the intermediate insulating layer MIF and the stack structure S_ST may be formed. In the process of forming the block separation structure WLC, the sacrificial layer 116 may be removed, and the word line 112 may be formed. For example, a through hole extending through the stack structure S_ST may be formed so as to form the block separation structure WLC. The sacrificial layer 116 may be selectively removed through the through hole formed as described above. In this case, the mold insulating layer 114 may remain. The word line 112 may be formed in the empty space that is generated upon removal of the sacrificial layer 116. As a result, the mold structure MS defined by the word line 112 and the mold insulating layer 114 may be formed. The through hole may be filled with an insulating material to form the block separation structure WLC. The channel layer 122 and the charge storage structure 124 formed on the upper surfaces of the intermediate insulating film MIF and the stack structure S_ST may be removed.

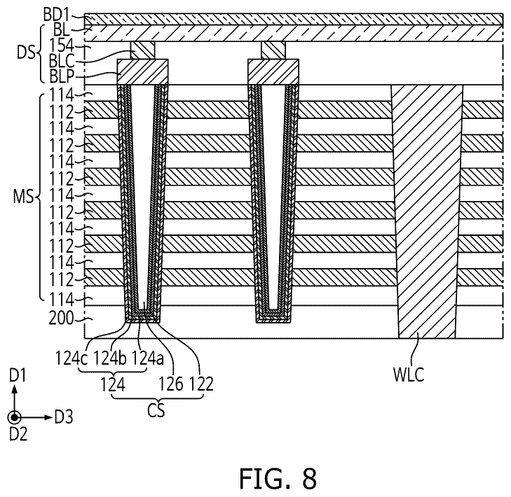

Referring to FIG. 8, a drain structure DS may be formed on a first surface of the mold structure MS. For example, the second interlayer insulating film 154 may be formed on the mold structure MS. The bit line contact pad BLP and the bit line contact BLC may be formed. The bit line contact pad BLP and the bit line contact BLC may extend through the second interlayer insulating film 154 and be connected to the channel layer 122. In addition, the bit line BL may be formed on the second interlayer insulating film 154 and the bit line contact BLC. The bit line contact pad BLP may be omitted. In addition, the first bonding structure BD1 for attaching to the peripheral circuit region PERI may be formed on the drain structure DS.

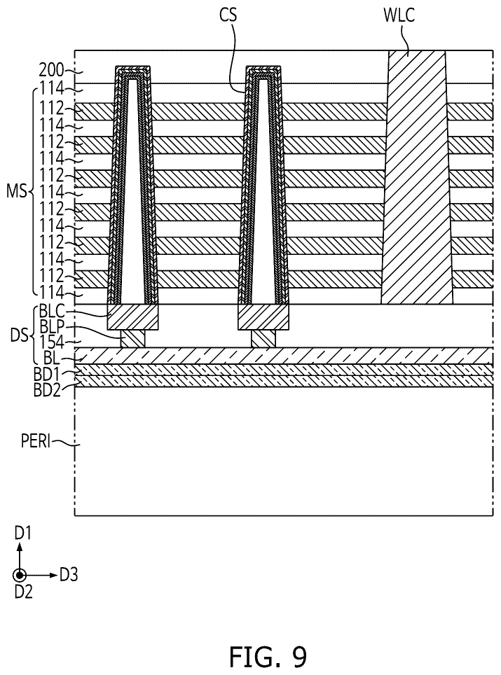

A process of forming the common source plate 100 on a second surface opposite the first surface of the mold structure MS will be described with reference to FIGS. 9 to 12. Referring to FIG. 9, the mold structure MS and the drain structure DS may be turned over such that the first bonding structure BD1 faces the second bonding structure BD2 formed on the peripheral circuit region PERI and is in contact with the same, and then the first bonding structure BD1 and the second bonding structure BD2 may be adhered to each other.

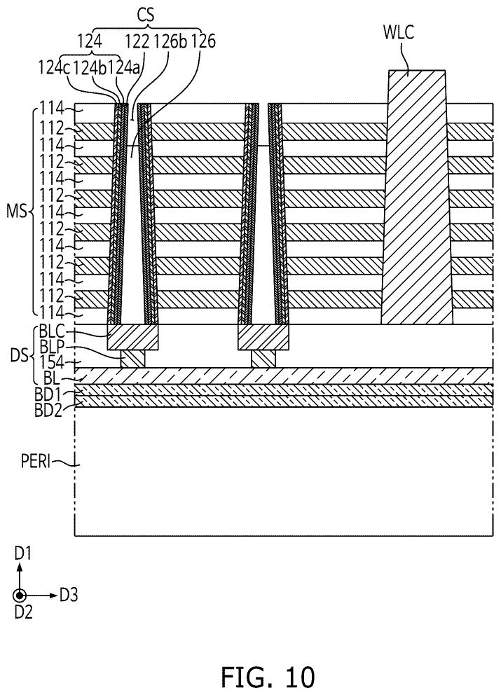

Referring to FIG. 10, the substrate 200 of the mold structure MS may be removed to expose at least a portion of the channel structure CS. For example, upon removal of the substrate 200, one end portion of the channel structure CS and a portion of the outer surface connected to the one end portion may be exposed. In this case, the exposed region of the channel structure CS may include the blocking insulating film 124c, the charge storage film 124b, the tunnel insulating film 124a, the channel layer 122, and the filling pattern 126 which are disposed in order from the outside.

The exposed region of the channel structure CS and the filling pattern 126 may be patterned to form the metal layer trench 126b. First, the blocking insulating film 124c, the charge storage film 124b, and the tunnel insulating film 124a may be patterned to expose a partial region of the channel layer 122 and the filling pattern 126. The channel layer 122 and the filling pattern 126 may be sequentially patterned to form the metal layer trench 126b. Accordingly, the patterned cross sections of the channel layer 122, the tunnel insulating film 124a, the charge storage film 124b, and the blocking insulating film 124c may be in substantially the same plane as the upper surface of the second surface of the mold structure MS. Meanwhile, as illustrated in FIGS. 4E and 4F, when patterning (e.g., etching) is actually performed, the patterned cross sections of the channel layer 122, the tunnel insulating film 124a, the charge storage film 124b, and the blocking insulating film 124c may have a lower vertical level than the upper surface of the second surface, and the vertical level of the corresponding cross section may gradually decrease from the outside to the inside of the channel structure CS.

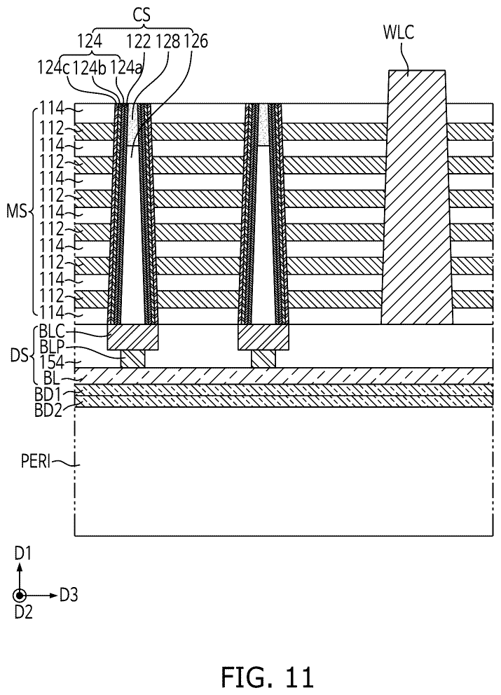

Referring to FIG. 11, the metal layer 128 may be formed to fill the metal layer trench 126b. The metal layer 128 may be disposed in one end region, that is, an upper region inside the channel structure CS. The metal layer 128 may be disposed on the filling pattern 126 and surrounded by the channel layer 122. The exposed cross section of the metal layer 128 may be in the same plane as the upper surface of the second surface of the mold structure MS.

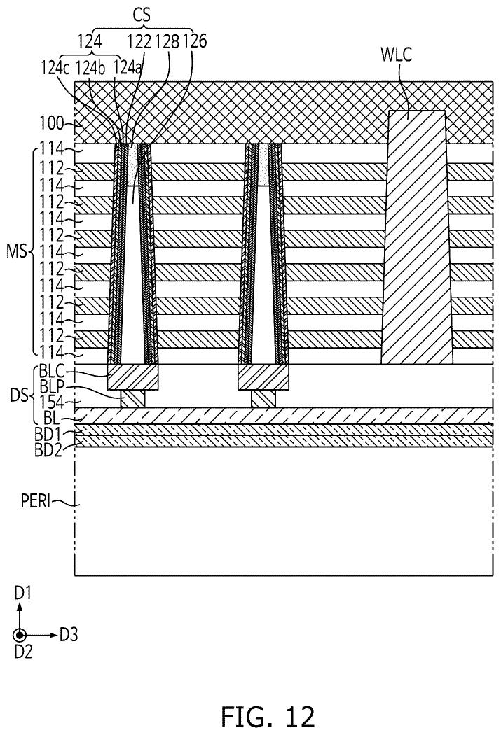

Referring to FIG. 12, the common source plate 100 may be formed to cover the second surface of the mold structure MS. The common source plate 100 may be formed by way of deposition on the second surface of the mold structure MS.

Accordingly, the channel layer 122 and the metal layer 128 may be in contact with, or at least electrically connected to the common source plate 100.

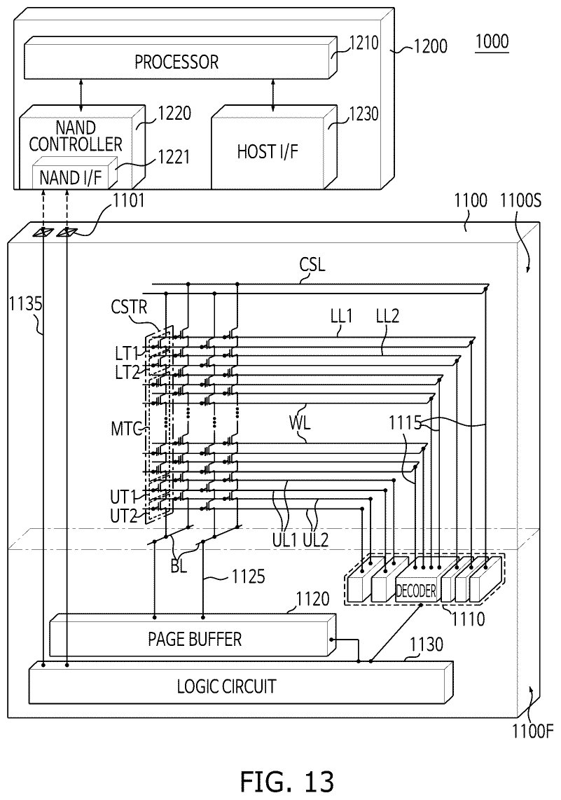

As a result, the integrated circuit memory devices 10, 10a, 10b, 10c, 10d, 10e, and 10f as described above with reference to FIGS. 1 to 4F may be provided. FIG. 13 is a conceptual diagram schematically illustrating an electronic system 1000 including an integrated circuit memory device 1100. Referring to FIG. 13, the electronic system 1000 may include the semiconductor device 1100 and a controller 1200 electrically connected to the semiconductor device 1100. The electronic system 1000 may be a storage device including one or a plurality of semiconductor devices 1100 or an electronic device including a storage device. For example, the electronic system 1000 may be a solid state drive device (SSD), a universal serial bus (USB), a computing system, a medical device, or a communication device including one or a plurality of semiconductor devices 1100.

For example, the semiconductor device 1100 may be a non-volatile memory device, for example, the NAND flash memory device described above with reference to FIGS. 1 to 4F. The semiconductor device 1100 may include a first structure 1100F and a second structure 1100S on the first structure 1100F. In some embodiments, the first structure 1100F may be disposed next to the second structure 1100S. The first structure 1100F may be a peripheral circuit structure including a decoder circuit 1110, a page buffer 1120, and a logic circuit 1130. The second structure 1100S may be a memory cell structure including a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each of the memory cell strings CSTR may include lower transistors LT1 and LT2 adjacent to the common source line CSL and upper transistors UT1 and UT2 adjacent to the bit line BL, and a plurality of memory cell transistors MCT disposed between the lower transistors LT1 and LT2 and the upper transistors UT1 and UT2. The number of the lower transistors LT1 and LT2 and the number of the upper transistors UT1 and UT2 may be modified according to various aspects.

In example aspects, the upper transistors UT1 and UT2 may include a string select transistor, and the lower transistors LT1 and LT2 may include a ground select transistor. The gate lower lines LL1 and LL2 each may be gate electrodes of the lower transistors LT1 and LT2. The word lines WL may be gate electrodes of the memory cell transistors MCT, and the gate upper lines UL1 and UL2 may be gate electrodes of the upper transistors UT1 and UT2, respectively.

The common source line CSL, the first and second gate lower lines LL1 and LL2, the word lines WL, and the first and second gate upper lines UL1 and UL2 may be electrically connected to the decoder circuit 1110 through first connection lines 1115 extending from within the first structure 1100F and to the second structure 1100S. The bit lines BL may be electrically connected to the page buffer 1120 through second connection wires 1125 extending from within the first structure 1100F and to the second structure 1100S.

In the first structure 1100F, the decoder circuit 1110 and the page buffer 1120 may perform a control operation on at least one memory cell transistor selected from among the plurality of memory cell transistors MCT. The decoder circuit 1110 and the page buffer 1120 may be controlled by the logic circuit 1130. The semiconductor device 1100 may communicate with the controller 1200 through an input and output pad 1101 electrically connected to the logic circuit 1130. The input and output pad 1101 may be electrically connected to the logic circuit 1130 through an input and output connection wiring 1135 extending from within the first structure 1100F and to the second structure 1100S.

The controller 1200 may include a processor 1210, a NAND controller 1220, and a host interface 1230. According to some aspects, the electronic system 1000 may include a plurality of semiconductor devices 1100, and in this case, the controller 1200 may control the plurality of semiconductor devices 1000.

The processor 1210 may control the overall operation of the electronic system 1000 including the controller 1200. The processor 1210 may operate according to predetermined firmware, and may control the NAND controller 1220 to access the semiconductor device 1100. The NAND controller 1220 may include a NAND interface 1221 that processes communication with the semiconductor device 1100. A control command for controlling the semiconductor device 1100, data to be written in the memory cell transistors MCT of the semiconductor device 1100, data to be read from the memory cell transistors MCT of the semiconductor device 1100, etc. may be transmitted through the NAND interface 1221. The host interface 1230 may provide a function of communication between the electronic system 1000 and an external host. Upon receiving a control command from the external host through the host interface 1230, the processor 1210 may control the semiconductor device 1100 in response to the control command.

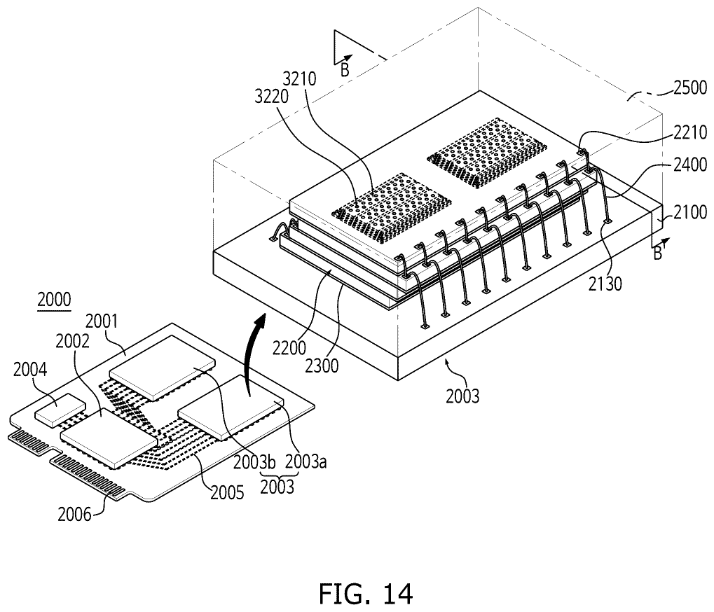

FIG. 14 is a perspective view schematically illustrating an electronic system 2000 including a 3D integrated circuit memory device according to aspects of the present disclosure. Referring to FIG. 14, the electronic system 2000 according to aspects of the present disclosure may include a main substrate 2001, a controller 2002 mounted on the main substrate 2001, one or more semiconductor packages 2003, and a DRAM 2004. The semiconductor package 2003 and the DRAM 2004 may be connected to the controller 2002 by wiring patterns 2005 provided to the main substrate 2001.

The main substrate 2001 may include a connector 2006 including a plurality of pins coupled to the external host. The number and arrangement of the plurality of pins in the connector 2006 may vary according to a communication interface between the electronic system 2000 and the external host. For example, the electronic system 2000 may communicate with the external host according to any one of interfaces such as Universal Serial Bus (USB), Peripheral Component Interconnect Express (PCI-Express), Serial Advanced Technology Attachment (SATA), M-Phy for Universal Flash Storage (UFS), Compute Express Link (CXL), Universal Chiplet Interconnect Express (UCIe), etc. For example, the electronic system 2000 may operate by the power supplied from the external host through the connector 2006. The electronic system 2000 may further include a Power Management Integrated Circuit (PMIC) that distributes the power supplied from the external host to the controller 2002 and the semiconductor package 2003.

The controller 2002 may record data in the semiconductor package 2003 or read data from the semiconductor package 2003, and may improve the operation speed of the electronic system 2000. The DRAM 2004 may be a buffer memory to alleviate the speed difference between the external host and the semiconductor package 2003 that is a data storage space. The DRAM 2004 included in the electronic system 2000 may also operate as a kind of cache memory, and may also provide a space for temporarily storing data in a control operation for the semiconductor package 2003. If the electronic system 2000 includes the DRAM 2004, in addition to the NAND controller for controlling the semiconductor package 2003, the controller 2002 may further include a DRAM controller for controlling the DRAM 2004.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chips 2200 on the package substrate 2100, adhesive layers 2300 disposed on a lower surface of each of the semiconductor chips 2200, a connection structure 2400 electrically connecting the semiconductor chips 2200 and the package substrate 2100, and a molding layer 2500 covering the semiconductor chips 2200 and the connection structure 2400 on the package substrate 2100.

The package substrate 2100 may be a printed circuit board including package upper pads 2130. Each of the semiconductor chips 2200 may include input and output pads 2210. Each of the semiconductor chips 2200 may include gate stack structures 3210 and vertical channel structures 3220. Each of the semiconductor chips 2200 may include the 3D integrated circuit memory device described above.

For example, the connection structure 2400 may be a bonding wire electrically connecting the input and output pads 2210 and the package upper pads 2130. In each of the first and second semiconductor packages 2003a and 2003b, the semiconductor chips 2200 may be electrically connected to each other with the bonding wire method, and may be electrically connected to the package upper pads 2130 of the package substrate 2100. According to some aspects, in each of the first and second semiconductor packages 2003a and 2003b, the semiconductor chips 2200 may be electrically connected to each other by through-electrodes (Through Silicon Via, TSV), instead of the bonding wire type connection structure 2400.

For example, the controller 2002 and the semiconductor chips 2200 may be included in one package. For example, the controller 2002 and the semiconductor chips 2200 may be mounted on a separate interposer substrate different from the main substrate 2001, and the controller 2002 and the semiconductor chips 2200 may be connected to each other by wiring provided on the interposer substrate.

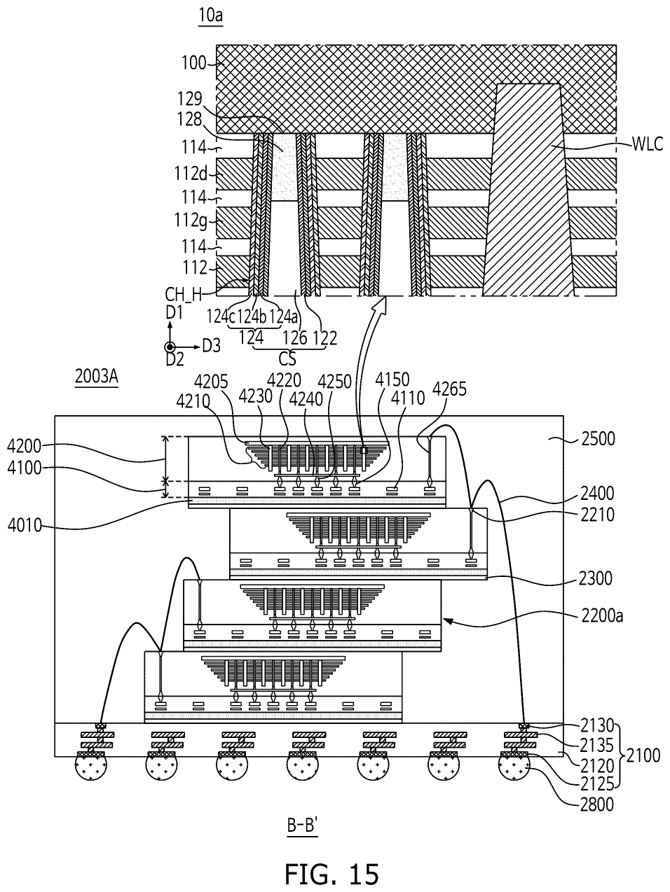

FIG. 15 is a cross-sectional view taken along the cross section B-B of FIG. 14. Referring to FIG. 15, the semiconductor package 2003 may include the package substrate 2100, the plurality of semiconductor chips 2200 on the package substrate 2100, and the molding layer 2500 covering the package substrate 2100 and a plurality of semiconductor chips.

The package substrate 2100 may include a package substrate body portion 2120, the package upper pads 2130 disposed on the upper surface of the package substrate body portion 2120, lower pads 2125 disposed on the lower surface of the package substrate body portion 2120 or exposed through the lower surface, and internal wires 2135 electrically connecting the upper pads 2130 and the lower pads 2125 inside the package substrate body portion 2120. The upper pads 2130 may be electrically connected to the connection structures 2400. The lower pads 2125 may be connected to the wiring patterns 2005 of a main substrate 2010 of the electronic system 2000 illustrated in FIG. 14 through conductive connection portions 2800.

Each of the semiconductor chips 2200 may include a semiconductor substrate 4010, a first structure 4100 on the semiconductor substrate 4010, and a second structure 4200 bonded to the first structure 4100 in a wafer bonding manner on the first structure 4100. The first structure 4100 may include a peripheral circuit region including a peripheral wiring 4110 and first bonding structures 4150. The second structure 4200 may include a common source line 4205, a gate stack structure 4210 between the common source line 4205 and the first structure 4100, memory channel structures 4220 and separation structures 4230 extending through the gate stack structure 4210, and second bonding structures 4250 electrically connected to the memory channel structures 4220 and the word lines WL of FIG. 1 of the gate stack structure 4210, respectively. For example, each of the second bonding structures 4250 may be electrically connected to the memory channel structures 4220 and the word lines (WL of FIG. 13) through the bit lines 4240 electrically connected to the memory channel structures 4220 and the gate connection wires electrically connected to the word lines (WL of FIG. 13). The first bonding structures 4150 of the first structure 4100 and the second bonding structures 4250 of the second structure 4200 may be bonded in contact with each other. The portions for bonding of the first bonding structures 4150 and the second bonding structures 4250 may be formed of copper (Cu). Each of the semiconductor chips 2200 may further include the input and output pad 2210 and input and output connection wiring 4265 under the input and output pad 2210. The input and output connection wiring 4265 may be electrically connected to some of the second bonding structures 4210. The semiconductor chips 2200 may be electrically connected to each other by the bonding wire type connection structures 2400. However, in example aspects, the semiconductor chips such as the semiconductor chips 2200 in one semiconductor package may be electrically connected to each other by the connection structure including a through-electrode TSV.

According to some aspects, in an electronic system, each of the semiconductor chips 2200 may include the integrated circuit memory devices 10, 10a, 10b, 10c, 10d, 10e, and 10f described above using FIGS. 1 to 4F. For example, the second structure 4200 of the semiconductor chips 2200 may include, as described above with reference to FIGS. 2 to 4f, the common source plate 100, a plurality of word lines 112 disposed on the bottom surface of the common source plate 100 and spaced apart from each other in the first direction D1 that is perpendicular to the bottom surface of the common source plate 100, the mold insulating layer 114 surrounding the plurality of word lines 112, the plurality of channel structures CS extending through the plurality of word lines 112 and the mold insulating layer 114 in the first direction D1, and the metal layer 128 disposed in the upper region inside the plurality of channel structures CS.

Although the present disclosure has been described above by way of certain aspects and drawings, the present disclosure is not limited thereto, and it goes without saying that various changes and modifications can be made within the equivalent scope of the technical idea of the present disclosure and the claims to be described below by those of ordinary skill in the art.

What is claimed is:

1. An integrated circuit memory device, comprising:
a common source plate having a semiconductor material of a first conductivity type therein;
a plurality of word lines including a dummy word line, which extend on a bottom surface of the common source plate and are spaced apart from each other in a first direction that is perpendicular to the bottom surface of the common source plate;
a mold insulating layer at least partially surrounding the plurality of word lines;
a plurality of channel structures extending through the plurality of word lines and the mold insulating layer in the first direction; and
a metal layer that extends in an upper region inside each of the plurality of channel structures, and is overlapped by the dummy word line in a horizontal direction, which is orthogonal to the first direction.

2. The memory device of claim 1, wherein the metal layer is in contact with inside of a channel layer of the plurality of channel structures and the bottom surface of the common source plate; and wherein a charge storage structure is provided, which extends outside the channel layer.

3. The memory device of claim 1, wherein the metal layer is in contact with inside of a channel layer of the plurality of channel structures and the bottom surface of the common source plate.

4. The memory device of claim 1, wherein the metal layer is in contact with the bottom surface of the common source plate, with at least a partial region of a side surface of the metal layer being in contact with the mold insulating layer.

5. The memory device of claim 1, wherein the metal layer includes a region that increases in width from inside the plurality of channel structures toward an upper portion.

6. The memory device of claim 1, wherein the metal layer includes at least one of aluminum (Al), titanium (Ti), and chromium (Cr).

7. The memory device of claim 1, wherein the semiconductor material of the common source plate is N-type polysilicon.

8. The memory device of claim 1, wherein the device is configured such that when a predetermined bias voltage is applied to the dummy word line, a Schottky barrier between the metal layer and the channel layer of the plurality of channel structures is lowered.

9. The memory device of claim 8, wherein the predetermined bias voltage has a negative voltage value.

10. The memory device of claim 1, wherein an uppermost end of the dummy word line has a lower vertical level than the upper surface of the metal layer; and wherein a lowermost end of the dummy word line has a higher vertical level than a lower surface of the metal layer.

11. The memory device of claim 1, wherein the dummy word line is positioned at an uppermost end of the plurality of word lines, and extends adjacent to a ground select line GSL of the plurality of word lines.

12. The memory device of claim 1, wherein the plurality of word lines include two or more dummy word lines, and the two or more dummy word lines are two or more word lines at an uppermost end of the plurality of word lines.

13. The memory device of claim 1,
wherein each of the plurality of channel structures includes: a channel hole extending through the plurality of word lines and the mold insulating layer in the first direction, and a charge storage structure and a channel layer stacked in order on an inner sidewall of the channel hole;
wherein a step is formed on the inner sidewall of the channel hole; and
wherein the metal layer extends into an upper region of the step.

14. An integrated circuit memory device, comprising:
a peripheral circuit region, and a memory cell region on the peripheral circuit region;
wherein the peripheral circuit region includes:
a peripheral circuit substrate;
a plurality of circuit elements formed on the peripheral circuit substrate;
a peripheral circuit wiring layer electrically connected to each of the plurality of circuit elements; and
an interlayer insulating layer that extends on the peripheral circuit substrate and surrounds the plurality of circuit elements and the peripheral circuit wiring layer;
wherein memory cell region includes:
a common source plate including a semiconductor material of a first conductivity type;
a plurality of word lines that extend on a bottom surface of the common source plate and are spaced apart from each other in a first direction perpendicular to the bottom surface of the common source plate;
a mold insulating layer surrounding the plurality of word lines;
a plurality of channel structures extending through the plurality of word lines and the mold insulating layer in the first direction;
a metal layer extending within an upper region inside each of the plurality of channel structures; and
a bit line extending under the plurality of channel structures;
wherein the plurality of word lines include a dummy word line; and
wherein at least a portion of the dummy word line overlaps the metal layer in a horizontal direction, which is orthogonal to the first direction.

15. The memory device of claim 14,
wherein the metal layer is in contact with an interior of a channel layer of the plurality of channel structures and the bottom surface of the common source plate; and
wherein a charge storage structure extends outside the channel layer.

16. The memory device of claim 14, wherein the metal layer is in contact with an interior of a charge storage structure of the plurality of channel structures and the bottom surface of the common source plate.

17. The memory device of claim 14, wherein the semiconductor material of the common source plate is N-type polysilicon.

18. The memory device of claim 14, wherein the memory device is configured such that when a predetermined bias voltage is applied to the dummy word line a Schottky barrier between the metal layer and the channel layer of the plurality of channel structures is lowered.

19. The memory device of claim 14,
wherein each of the plurality of channel structures includes: a channel hole, which extends through the plurality of word lines and the mold insulating layer in the first direction, and a charge storage structure and a channel layer that are stacked in order on an inner sidewall of the channel hole;
wherein a step is formed on the inner sidewall of the channel hole; and
wherein the metal layer extends within an upper region of the step.

20. An integrated circuit memory device, comprising:
a common source plate including N-type polysilicon;
a plurality of word lines that extend on a bottom surface of the common source plate, and are spaced apart from each other in a first direction, which is perpendicular to the bottom surface of the common source plate;
a mold insulating layer at least partially surrounding the plurality of word lines;
a plurality of channel structures extending through the plurality of word lines and the mold insulating layer in the first direction;
a metal layer extending within an upper region inside each of the plurality of channel structures, and contacting an inside of a channel layer of the plurality of channel structures and the bottom surface of the common source plate; and
a bit line extending under the plurality of channel structures;
wherein the plurality of word lines include a dummy word line;
wherein the memory device is configured such that an application of a predetermined bias voltage to the dummy word line lowers a Schottky barrier between the metal layer and the channel layer; and
wherein at least a portion of the dummy word line overlaps the metal layer in a horizontal direction, which is orthogonal to the first direction.
